(19) United States
(12) Patent Application Publication
(10) Pub. No.: US 2006/0183061 A1
(43) Pub. Date: Aug. 17, 2006

(54) Method for forming positive metal pattern and EMI filter using the same

(75) Inventors: Euk Che Hwang, Osan-si (KR); Chang Ho Noh, Suwon-si (KR); Sung Hen Cho, Seoul (KR); Ki Yong Song, Seoul (KR); Jin Young Kim, Suwon-si (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Corning Co., Ltd., Suwon-si (KR)

(21) Appl. No.: 11/325,339

(22) Filed: Jan. 5, 2006

(30) Foreign Application Priority Data
Jan. 7, 2005 (KR) 2005-0001762

(51) Int. Cl. G03F 7/00

(52) U.S. Cl. 430/324; 430/322

(57) ABSTRACT

A method for forming a positive metal pattern that includes the steps of (i) coating a photocatalytic compound on a substrate to form a photocatalytic film, (ii) coating a composition comprising a water-soluble polymer and a Pd compound on the photocatalytic film to form a photosensitive layer, (iii) selectively exposing the photocatalytic film and the photosensitive layer to light to form a latent pattern acting as a nucleus for crystal growth, and (iv) plating the latent pattern to grow a metal crystal thereon. Further disclosed is an electromagnetic interference (EMI) filter comprising a metal pattern formed by the method. According to the method, a high-resolution metal pattern can be formed in a rapid and efficient manner when compared to conventional methods for forming a metal pattern. In addition, since the EMI filter has superior performance and is easy to manufacture at low costs, it can be advantageously applied to flat display panels, including plasma display panels (PDPs).

### CROSS-REFERENCE TO RELATED PATENT APPLICATION

This non-provisional application claims priority under 35 U.S.C. § 119(a) to Korean Patent Application No. 2005-1762 filed on Jan. 7, 2005, which is herein incorporated by reference

### BACKGROUND OF THE INVENTION

1. Field of the Invention

Embodiments of the present invention relate to a method for forming a positive metal pattern and an electromagnetic interference filter (EMI) filter manufactured using a metal pattern formed by the method. More particularly, embodiments of the present invention relate to a method for forming a high-resolution positive metal pattern with superior processability by forming a metal wiring using a photocatalyst and growing a metal on UV-unexposed portions by positive patterning, a metal pattern obtained by the method, and an EMI filter comprising the metal pattern formed by the method. A low-resistivity metal pattern can be formed in a rapid and efficient manner by a method of embodiments of the present invention when compared to conventional methods for forming a metal pattern. In addition, since the EMI filter comprising a metal pattern formed by a method of embodiments of the present invention has superior performance and is easy to manufacture at low costs, it can be advantageously applied to flat display panels, including plasma display panels (PDPs).

2. Description of the Related Art

In recent years, with drastically increasing demand for various display devices, including plasma display panels (PDPs) used as wall-mounted televisions, studies on techniques for shielding static electricity and harmful electromagnetic waves emitted from the display devices are actively being undertaken. In this connection, Japanese Patent Laid-open No. Hei 11-119675 discloses a process for manufacturing an electromagnetic wave shielding plate arranged on the front surface of a display wherein a mesh made of a metal thin film is laminated on one side of a transparent substrate. This process is suitable for mass production of an electromagnetic wave shielding plate with superior electromagnetic wave shielding properties and see-through properties. Specifically, the process comprises the steps of (a) forming (masking) a plating resist mask for plating a mesh on a continuous hoop-shaped substrate having plating stripping properties, (b) electrodepositing a metal thin-film layer made of a particular material for mesh formation on portions of the substrate surface not covered by the resist mask, and (c) adhering and transferring the electrodeposited metal thin-film layer to a surface of the transparent substrate for the electromagnetic wave shielding plate using an adhesive. However, the process is disadvantageous because of its complicated procedure.

As another example, Japanese Patent Laid-open No. Hei 5-16281 discloses a light-transmitting electromagnetic wave shielding material comprising a substrate, a hydrophilic transparent resin layer laminated on the substrate and an electroless plating layer laminated on a pattern of the resin layer wherein a black pattern section is formed between the electroless plating layer and the hydrophilic transparent resin layer. However, the shielding material suffers from the drawback that both photoresist and etching processes are also required.

Japanese Patent Laid-open No. 2003-109435 discloses a method for producing a transparent conductive film comprising forming a metallic ultrafine particle catalyst layer having a prescribed pattern on a transparent substrate, and forming a metal layer on the catalyst layer wherein the ratio of the average opening diameter to the average line width of the pattern is above 7:1. However, a drawback of this method is the use of an ultrafine particle catalyst.

There is thus a need in the art for a method for forming a metal pattern in a cost-effective and simple manner. Under these circumstances, embodiments of the present invention may provide an improved method for forming a positive type metal pattern in a simplified and efficient manner.

### OBJECTS AND SUMMARY

The present inventors have earnestly and intensively conducted research to solve the above-mentioned problems. As a result, the present inventors have found, according to an embodiment of the present invention, that a positive metal pattern can be formed in a rapid and simple manner by forming a photosensitive layer on a photocatalytic film, selectively exposing the photosensitive layer and the photocatalytic film to light to form a latent pattern acting as a nucleus for crystal growth, and plating the latent pattern to grow a metal crystal thereon, when compared to conventional methods. In addition, the present inventors have found that an electromagnetic interference filter manufactured using the metal pattern, according to an embodiment of the present invention, has superior performance and is simple to manufacture at low costs, and can thus be advantageously applied to flat display panels, including PDPs. Embodiments of the present invention has been achieved based on these findings.

Therefore, it is one object of embodiments of the present invention to provide a method for rapidly and efficiently forming a fine metal pattern by a simple process without the necessity of a metal thin-film formation process requiring high vacuum/high temperature, a light-exposure process for developing a minute pattern, or a subsequent etching process.

It is another object of embodiments of the present invention to provide an electromagnetic interference filter comprising a metal pattern formed by the method.

In accordance with one aspect of embodiments of the present invention for achieving the above objects, there is provided a method for forming a positive metal pattern, the method comprising the steps of (i) coating a photocatalytic compound on a substrate to form a photocatalytic film, (ii) coating a composition comprising a water-soluble polymer and a Pd compound on the photocatalytic film to form a photosensitive layer, (iii) selectively exposing the photocatalytic film and the photosensitive layer to light to form a latent pattern acting as a nucleus for crystal growth, and (iv) plating the latent pattern to grow a metal crystal thereon.

In accordance with another aspect of embodiments of the present invention, there is provided a positive metal pattern formed by the method.

In accordance with yet another aspect of embodiments of the present invention, there is provided an electromagnetic interference filter comprising the positive metal pattern.

### BRIEF DESCRIPTION OF THE DRAWINGS

The above and other objects, features and other advantages of embodiments of the present invention will be more clearly understood from the following detailed description taken in conjunction with the accompanying drawings, in which:

FIG. 1 schematically shows a method for forming a positive metal pattern according to one embodiment of the present invention;

FIG. 2 shows images of a positive metal pattern formed by a method of embodiments of the present invention and a mask used to form the positive metal pattern;

FIG. 3 show images before and after exposure of a photosensitive layer formed in accordance with a method of embodiments of the present invention; and

FIG. 4 show images taken at different magnifications of a pattern formed in Example 1 of embodiments of the present invention.

### DESCRIPTION OF THE PREFERRED EMBODIMENTS

Embodiments of the present invention will now be described with reference to the accompanying drawings. A method of embodiments of the present invention will be explained in more detail based on the respective steps.

Step (i):

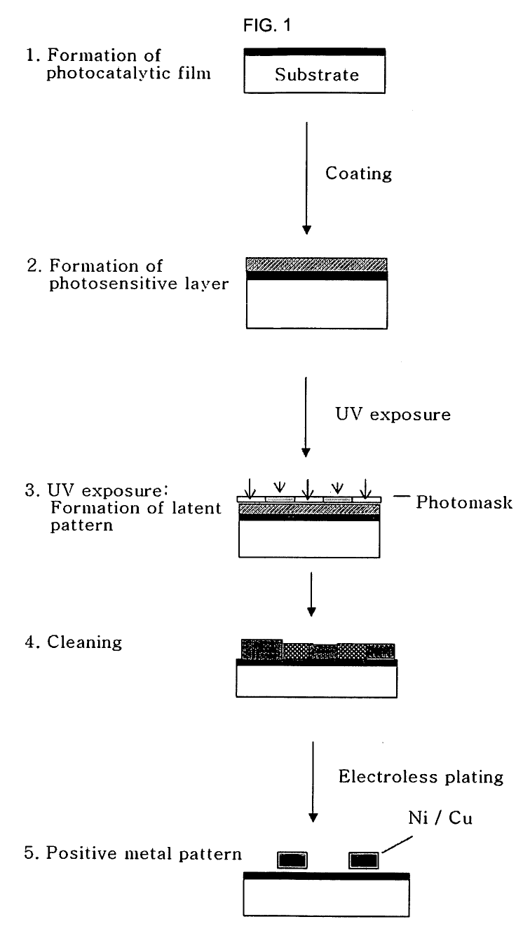

FIG. 1 schematically shows a method for forming a positive metal pattern according to one embodiment of embodiments of the present invention. First, as shown in FIG. 1, a photocatalytic compound is coated on a substrate to form a photocatalytic film.

The term “photocatalytic compound” as used herein refers to a compound whose characteristics are changed by light. That is, the photocatalytic compound shows different characteristics before and after exposure to light. Specifically, some photocatalytic compounds are inactive when not exposed to light, but their reactivity is accelerated upon being exposed to light, e.g., UV light. Alternatively, some photocatalytic compounds are active when not exposed to light, but their reactivity is lost upon exposure to light, e.g., UV light, and eventually they become inactive. The photocatalytic compound preferably used in embodiments of the present invention is a compound that is inactive before exposure to light but is electron-excited by photoreaction after exposure to light to have a reducing ability. As the photocatalytic compound, there can be used, for example, a Ti-containing organometallic compound which can form TiOₓ (in which x is a number not greater than 2) upon exposure to light.

Specific examples of Ti-containing organometallic compounds include tetraisopropyl titanate, tetra-n-butyl titanate, tetrakis(2-ethyl-hexyl) titanate, and polybutyl titanate.

The photocatalytic compound can be dissolved in an appropriate solvent, e.g., isopropyl alcohol, and coated on a transparent substrate by spin coating, spray coating, screen printing, or the like.

Examples of preferred substrates that can be used in embodiments of the present invention include, but are not especially limited to, transparent plastic substrates and glass substrates. As materials for the transparent plastic substrates, there can be used acrylic resins, polyesters, polycarbonates, polyethylenes, polyethersulfones, olefin-maleimide copolymers, norbornene-based resins, and the like. In the case where excellent heat resistance is required, olefin-maleimide copolymers and norbornene-based resins are preferred. Otherwise, it is preferred to use polyester films, acrylic resins, and the like.

The coating layer thus formed preferably has a thickness of 30 nm to 1,000 nm. After coating, the coated structure is preferably heated on a hot plate or a convection oven at a temperature of, preferably, 150° C. or below for, preferably, 20 minutes or less to form a photocatalytic film. More preferably, the heating is preformed at a temperature of 100° C. or below for 5 minutes or less.

Step (ii):

In this step, a photosensitive layer is formed on the photocatalytic film formed in step (i). Specifically, the photosensitive layer is formed by coating a composition comprising a water-soluble polymeric compound and a Pd compound on the photocatalytic film. Since the Pd compound contained in the composition is originally active, the composition is active before exposure to light but loses its activity by photooxidation in the subsequent light exposure step.

Examples of preferred water-soluble polymers include homopolymers, such as polyvinylalcohols, polyvinylphenols, polyvinylpyrrolidones, polyacrylic acids, polyacrylamides, gelatins, etc., and copolymers thereof. Examples of preferred Pd compounds include Pd(NO₃)₂(NH₃)₄, Pd(NO₂)₂(NH₃)₂, Pd(NH₃)₄Br₂, and Pd(NH₃)₄(CH₃CO₂)₂.

Even when a slight amount of the Pd compound is present in the composition, the subsequent light exposure step may leave a desired latent pattern. The mixing ratio between the water-soluble polymer and the Pd compound is preferably in the range of 5:1 to 200:1, but is not limited to this range.

1-10% by weight of the water-soluble polymer is dissolved in water before use.

If necessary, the composition further comprises a photosensitizer selected from organic acids, such as citric acid, ascorbic acid, formic acid, malic acid and oxalic acid, ammonium citrate, sodium citrate, K-tartrate, Na-tartrate, tar colorants, potassium and sodium salts of chlorophylline, riboflavin and derivatives thereof, water-soluble soluble annatto, CuSO₄, caramel, curcumine, cochinal, organic amines, such as triethanolamine and monoethanolamine, and water-soluble alcohols, such as methanol, ethanol, butanol and 2-propanol. It is more effective to use the organic acid in an amount of 1-10% by weight, the organic amine in an amount of 0.1-5% by weight and the water-soluble alcohol in an amount of 0.05-5% by weight in the composition for forming the photosensitive layer, but the amounts of the photosensitizers used are not limited to these ranges.

The composition thus prepared is coated on the photocatalytic film formed in step (i) by common coating processes.

After coating, the coated structure can be optionally dried by heating to a temperature of, preferably, 150° C. or below for, preferably, 20 minutes or less to form a photosensitive layer. Preferably, the heating is preformed at a temperature of 100° C. or below for 5 minutes or less. The thickness of the photosensitive layer is preferably controlled to 200-1,000 Å.

Step (iii):

The photosensitive layer is selectively exposed to UV light using, preferably, a glass or quartz photomask to form a latent pattern acting as a nucleus for crystal growth, which consists of active and inactive portions. Any suitable photomask can be properly selected.

At this time, exposure atmospheres and exposure doses are not especially limited, and can be properly selected according to the kind of photocatalyst compounds used.

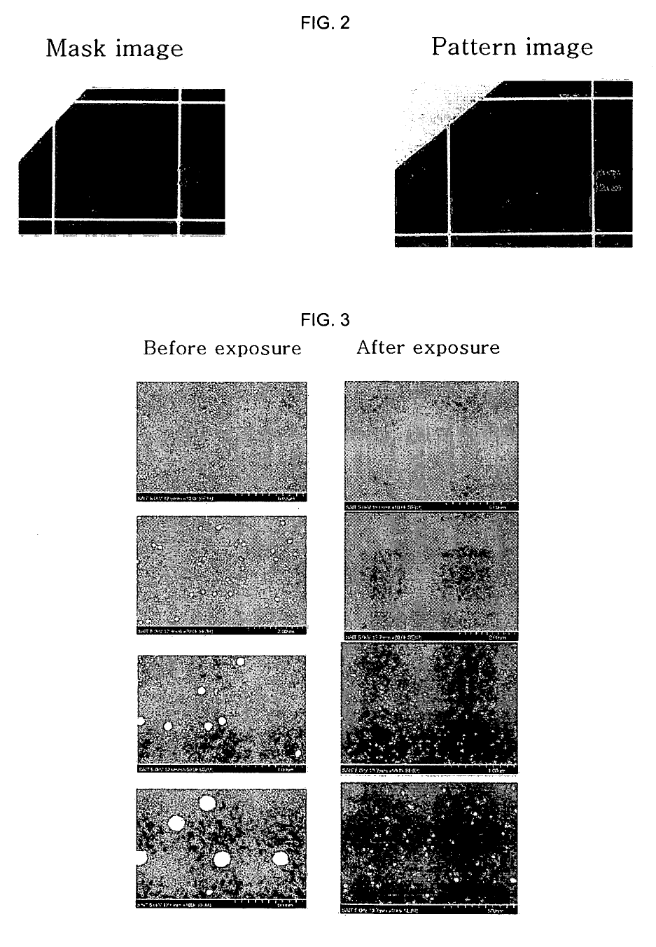

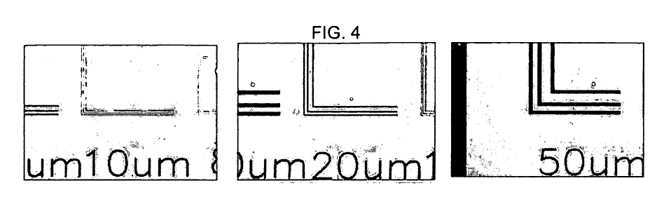

After UV exposure, the exposed portions should produce little or no metal crystals, while the unexposed portions should produce metal crystals to be grown in the subsequent plating step, thus leaving a positive pattern having the same shape as that of the mask, as shown in FIG. 2. The reason for the formation of the positive pattern is that the surface characteristics of the photosensitive layer are changed by UV exposure. FIG. 3 shows images before and after UV exposure of the surface of the photosensitive layer. As is apparent from the images shown in FIG. 3, the size of the Pd particles present on the surface of the photosensitive layer before light exposure is different from that of the Pd particles present on the surface of the photosensitive layer after light exposure. It is to be appreciated that the difference in the reactivity between the exposed and unexposed portions in the subsequent plating step arises from the difference in the Pd crystal size. Specifically, the crystal size of the Pd particles present on the surface of the photosensitive layer before light exposure is between 50 and 100 nm, while that of the Pd particles present on the surface of the photosensitive layer after light exposure is 10 nm or less. It is understood that since the latter Pd particles having a larger surface area are sufficiently oxidized when in contact with air, e.g., oxygen, they exhibit no reactivity in the subsequent plating step.

After exposure, the exposed surface is cleaned with a water-soluble solvent to leave the desired latent pattern. Accordingly, pretreatment steps required prior to plating in conventional methods, including treatment with a Pd solution or Fe, may be omitted.

Step (iv):

In this step, the latent pattern formed in step (iii) is subjected to plating to grow a metal crystal on the latent pattern, completing the formation of the final positive metal pattern. The plating is preferably performed by electroless plating.

Plating metals, e.g., Cu, Ni, Ag, Au and alloys thereof, usable for the plating in embodiments of the present invention can be properly selected according to the application of metal patterns. To form a highly conductive metal pattern, a copper or silver compound solution is preferably used.

The electroless plating may be achieved in accordance with well-known procedures. A more detailed explanation will be described below.

In the case where an electroless plating process is employed to grow a copper crystal, the substrate on which the pattern for crystal growth is formed is dipped in a plating solution having a composition comprising 1) a copper salt, 2) a reducing agent, 3) a complexing agent, 4) a pH-adjusting agent, 5) a pH buffer, and 6) a modifying agent. The copper salt 1) serves as a source providing copper ions to the substrate. Examples of the copper salt include chlorides, nitrates, sulfates, and cyanides of copper. Copper sulfates are preferred. The reducing agent 2) acts to reduce metal ions present on the substrate. Specific examples of the reducing agent include NaBH₄, KBH₄, NaH₂PO₂, hydrazine, formalin, and polysaccharides (e.g., glucose). Formalin and polysaccharides (e.g, glucose) are preferred. The complexing agent 3) functions to prevent precipitation of hydroxides in an alkaline solution and to control the concentration of free metal ions, thereby preventing the decomposition of metal salts and adjusting the plating speed. Specific examples of the complexing agent include ammonia solution, acetic acid, guanic acid, tartaric acid, chelating agents (e.g., EDTA), and organic amine compounds. Chelating agents (e.g., EDTA) are preferred. The pH-adjusting agent 4) serves to adjust the pH of the plating solution, and is selected from acidic and basic compounds. The pH buffer 5) inhibits sudden changes in the pH of the plating solution, and is selected from organic acids and weakly acidic inorganic compounds. The modifying agent 6) is a compound capable of improving coating and planarization characteristics. Specific examples of the modifying agent include common surfactants, and adsorptive substances capable of adsorbing components interfering with the crystal growth.

In the case where an electroless plating process is employed to grow a silver crystal, the pattern is dipped in a plating solution having a composition comprising 1) a silver salt, 2) a reducing agent, 3) a complexing agent, 4) a pH-adjusting agent, 5) a pH buffer, and 6) a modifying agent. The silver salt 1) serves as a source providing silver ions to the metal patter. Specific examples of the silver salt include chlorides, nitrates and cyanides of silver. Silver nitrates are preferred. The functions and the specific examples of the other components contained in the plating solution composition are as defined above.

The constitution and effects of embodiments of the present invention will be described in more detail with reference to the following specific examples. However, these examples serve to provide further appreciation of the invention but are not meant in any way to restrict the scope of the invention.

### EXAMPLE 1

(1) Formation of Latent Pattern Acting as Nucleus for Crystal Growth

A solution of polybutyl titanate in isopropanol was applied to a transparent polyester substrate by spin coating, and dried at 100° C. for 5 minutes to form a photocatalytic film. At this time, the photocatalytic film was controlled to have a thickness of about 400 Å. 10 g of polyvinyl alcohol, 12 g of citric acid, 1 ml of triethanolamine, 20 ml of 2-propanol and 0.1 g of Pd(NO₃)₂(NH₃)₄ were mixed in water to prepare 200 ml of a composition, and then the composition was spin-coated to a thickness of about 1,300 Å on the photocatalytic film to form a photosensitive layer. A Cr photomask on which a fine mesh pattern was formed was positioned on the photosensitive layer, and irradiated with UV rays in a broad range of wavelengths using a UV exposure system (Oriel, U.S.A). Thereafter, cleaning was performed using deionized water.

(2) Formation of Positive Type Copper Wiring by Electroless Copper Plating

The substrate prepared above was dipped in an electroless copper plating solution to selectively grow a metal crystal of a desired pattern. The electroless copper plating solution was prepared so as to have the composition indicated in Table 1 below. Images of the copper wiring are shown in FIG. 4, and the basic physical properties of the copper wiring are shown in Table 2 below. The thickness was measured using an alpha step (manufactured by Dektak), the resistivity was measured using a 4-point probe. The resolution was determined using an optical microscope, and the adhesive force was evaluated by a scotch tape peeling test. The electromagnetic wave shielding effect was evaluated by measuring the transmittance of an electromagnetic wave having a frequency range of 30 MHz to 1,000 MHz.

### EXAMPLE 2

A latent pattern was formed in the same manner as in Example 1, except that the photosensitive layer was formed using 200 ml of a composition prepared by mixing 10 g of polyvinyl alcohol, 12 g of citric acid, 1 ml of triethanolamine and 0.1 g of Pd(NO₃)₂(NH₃)₄ in water. Thereafter, the latent pattern was subjected to electroless copper plating to form a positive type copper wiring.

### EXAMPLE 3

A latent pattern was formed in the same manner as in Example 1, except that the photosensitive layer was formed using 200 ml of a composition prepared by mixing 10 g of polyvinyl alcohol, 12 g of citric acid and 0.1 g of Pd(NO₃)₂(NH₃)₄ in water. Thereafter, the latent pattern was subjected to electroless copper plating to form a positive type copper wiring.

### COMPARATIVE EXAMPLE 1

A latent pattern was formed in the same manner as in Example 1, except that the photosensitive layer was formed using 200 ml of a composition prepared by mixing 10 g of polyvinyl alcohol, 12 g of citric acid, 1 ml of triethanolamine and 20 ml of 2-propanol in water. Thereafter, a Pd pattern was selectively formed on exposed portions using a 0.3% PdCl₂ solution, followed by electroless copper plating to form a negative type copper wiring.

TABLE 1
Copper plating solution

| | | |
|---|---|---|
| Copper sulfate: | 3.5 | g |
| Rochelle salt: | 8.5 | g |
| Formalin (37%): | 22 | ml |
| Thiourea: | 1 | g |
| Ammonia: | 40 | g |
| Water: | 1 | liter |
| 35° C./5 min. | | |

TABLE 2

| | | | | | Electro- |
|---|---|---|---|---|---|
| | | | | | magnetic |
| | Thick- | | | | wave shielding |
| Example | ness | Resistivity | Resolution | | effect |
| No. | (μm) | (μΩ-cm) | (μm) | Adhesion | (at 100 MHz) |
| Example 1 | 1.7 | 1.2 | 8 | Good | 51 |
| Example 2 | 2.0 | 1.0 | 11 | Good | 55 |
| Example 3 | 1.7 | 1.2 | 9 | Good | 53 |
| Com- | 2.3 | 0.9 | 13 | Good | 55 |
| parative | | | | | |
| Example 1 | | | | | |

As apparent from the above description, embodiments of the present invention provides a method for forming a positive metal pattern by forming a photocatalytic film and a photosensitive layer through a simple coating process, followed by plating. According to methods of embodiments of the present invention, since an increase in line width caused from scattering of UV light, which commonly occurs during formation of positive metal patterns, can be prevented, a high-resolution positive metal pattern can be formed. In addition, an EMI filter manufactured using a metal pattern formed by methods of embodiments of the present invention not only exhibits performance comparable to conventional EMI filters, but also is advantageously manufactured through a simple process at reduced costs.

Although the preferred embodiments of embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method for forming a positive metal pattern, the method comprising the steps of:
(i) coating a photocatalytic compound on a substrate to form a photocatalytic film;
(ii) coating a composition comprising a water-soluble polymer and a Pd compound on the photocatalytic film to form a photosensitive layer;
(iii) selectively exposing the photocatalytic film and the photosensitive layer to light to form a latent pattern acting as a nucleus for crystal growth; and
(iv) plating the latent pattern to grow a metal crystal thereon.

2. The method according to claim 1, wherein the water-soluble polymer used in step (ii) is at least one polymer selected from the group consisting of polyvinylalcohols, polyvinylphenols, polyvinylpyrrolidones, polyacrylic acids, polyacrylamides, gelatins, and copolymers thereof; and the Pd compound is at least one compound selected from the group consisting of Pd(NO₃)₂(NH₃)₄, Pd(NO₂)₂(NH₃)₂, Pd(NH₃)₄Br₂, and Pd(NH₃)₄(CH₃CO₂)₂.

3. The method according to claim 1, wherein the water-soluble polymer and the Pd compound used in step (ii) are mixed in a ratio of 5:1 to 200:1.

4. The method according to claim 2, wherein the composition used in step (ii) further comprises at least one compound selected from the group consisting of organic acids, organic amines, and water-soluble alcohols.

5. The method according to claim 4, wherein the organic acid is used in an amount of 1-10% by weight, the organic amine is used in an amount of 0.1-5% by weight, and the water-soluble alcohol is used in an amount of 0.05-5% by weight in the composition.

6. The method according to claim 1, wherein the photocatalytic compound used in step (i) is a Ti-containing organometallic compound which forms TiOₓ (in which x is a number not greater than 2) upon exposure to light.

7. The method according to claim 6, wherein the Ti-containing organometallic compound is selected from the group consisting of tetraisopropyl titanate, tetra-n-butyl titanate, tetrakis(2-ethyl-hexyl) titanate, and polybutyl titanate.

8. The method according to claim 1, wherein the plating in step (iv) is performed by electroless plating.

9. The method according to claim 1, wherein the plating in step (iv) is performed using at least one plating metal selected from the group consisting of Cu, Ni, Ag, Au, and alloys thereof.

10. A positive metal pattern formed by the method according to claim 1.

11. An electromagnetic interference filter comprising a positive metal pattern formed by the method according to claim 1.

12. A flat panel display comprising the electromagnetic interference filter according to claim 11.
